(19) United States
(12) Patent Application Publication
(10) Pub. No.: US 2010/0079641 A1
(43) Pub. Date: Apr. 1, 2010

(54) IMAGING APPARATUS AND METHOD FOR DRIVING SOLID-STATE IMAGING ELEMENT

(75) Inventor: Takashi GOTO, Kanagawa (JP)

Correspondence Address: Studebaker & Brackett PC, One Fountain Square, 11911 Freedom Drive, Suite 750, Reston, VA, 20190, US

(73) Assignee: FUJIFILM CORPORATION, Tokyo (JP)

(21) Appl. No.: 12/568,550

(22) Filed: Sep. 28, 2009

(30) Foreign Application Priority Data
Sep. 29, 2008 (JP) P2008-251883

(51) Int. Cl. H04N 5/335

(52) U.S. Cl. 348/294; 348/E05.091

(57) ABSTRACT

In an imaging apparatus having a plurality of pixel portions containing photoelectric converting portions, each of the pixel portions is provided with a writing transistor and a reading transistor, which contain a floating gate provided above a semiconductor substrate in order to store thereinto electric charges generated in the photoelectric converting portion; and a control portion for performing such a driving operation that the electric charges stored in the floating gate are ejected to a writing drain of the writing transistor and a reading drain of the reading transistor.

The present application claims priority from Japanese Patent Application No. 2008-251883 filed on Sep. 29, 2008, the entire content of which is incorporated herein by reference.

### BACKGROUND OF INVENTION

1. Field of the Invention

The present invention is related to an imaging apparatus having a plurality of pixel portions containing photoelectric converting portions.

2. Description of the Related Art

A solid-state imaging apparatus for performing an imaging operation in the following manner has been proposed (refer to JP-A-2002-280537): That is, in the above-described solid-state imaging apparatus, electric charges generated in a photoelectric converting element such as a photodiode (PD) are injected into a floating gate (FG) of a MOS transistor, which functions as an electric charge storage portion, so as to be stored in the floating gate (FG), and then, signals responding to the electric charges stored in the FG are read out from the MOS transistor to an external unit.

In the solid-state imaging apparatus described in JP-A-2002-280537, after the signals responding to the electric charges stored in the FG have been read out, electric charges which are present in the FG are required to be removed (erased) in order to prepare for the next exposing operation. Also, a solid-state imaging apparatus is not required for storing thereinto data (namely, retention characteristic) for a long time, which is different from a semiconductor memory. Since electric charges are erased in a high speed after a signal has been read out from the solid-state imaging apparatus, a subsequent imaging operation can be carried out, so that a frame rate thereof can be increased.

JP-A-2002-280537 has disclosed such an electric charge erasing method. That is, since negative voltages are applied to the control gate of the writing transistor and the control gate of the reading transistor, and also, the positive voltage is applied to the semiconductor substrate (10), electric charges stored in the FG are drawn out to the semiconductor substrate (10) in order to erase these electric charges. In this method, the electric charge drawing operation can be carried out in the high speed by increasing the voltage applied to the semiconductor substrate (10).

However, if the voltage applied to the semiconductor substrate (10) is increased, then the below-mentioned risks may occur. That is, gate oxide films may be increased, the potential of the semiconductor substrate (10) may be modulated, dark currents appeared in the vicinity of source-to-drain junction portions of transistors may be increased, and other risks may occur. Also, there is another risk that electric charges ejected from the FG cannot be completely drawn out to the semiconductor substrate (10), but are left in the p type region (20) within the semiconductor substrate (10), and thus, the remaining electric charges may be mixed in the signal of the next frame as the noise.

### SUMMARY OF INVENTION

The present invention has been made to solve the above-described problems, and therefore, has an object to provide an imaging apparatus and a method of driving a solid-state imaging element, capable of erasing electric charges stored in electric charge storage portions, while suppressing noises.

An imaging apparatus, according to an aspect of the present invention, a photoelectric converting portion in each of a plurality of pixel portions; a transistor which includes an electric charge storage portion provided above a semiconductor substrate so as to store thereinto electric charges generated in each of the photoelectric converting portions; and an electric charge ejecting unit which ejects the electric charges stored in the electric charge storage portion to a drain region of the transistor.

With employment of the above-described structure, the electric charges stored in the electric charge storage portion of each of the pixel portions are ejected to the drain region of the transistor. As a result, as compared with the conventional solid-state imaging element in which the electric charges are ejected to the semiconductor substrate, the imaging apparatus of the present invention can avoid that oxide films of a surface of the semiconductor substrate are deteriorated, a potential at the semiconductor substrate is modulated, dark currents produced in the vicinity of a source-to-drain junction portion of the transistor is increased. Moreover, the above-described imaging apparatus of the present invention can avoid that the electric charges ejected from the electric charge storage portion are left in the semiconductor substrate. As a result, such a risk that the remaining electric charges are mixed to an imaging signal of a next frame as noises can also be reduced.

In the imaging apparatus of the present invention, the electric charge ejecting unit applies a voltage having a first polarity to a gate electrode of the transistor and applies another voltage having a second polarity opposite to the first polarity to the drain region of the transistor so as to eject the electric charges stored in the charge storage portion to the drain region.

In the imaging apparatus of the present invention, each of the plurality of the pixel portions has two sets of the transistors; wherein one transistor is a writing transistor which stores the electric charges by injecting the electric charges to the electric charge storage portion, and the other transistor is a reading transistor which reads a signal in response to the electric charges stored in the electric charge storage portion; the electric charge storage portion corresponds to a floating gate, while the floating gate included in the writing transistor has been electrically connected to the floating gate included in the reading transistor; and the electric charge ejecting unit applies the voltage having the first polarity with respect to the gate electrode of the writing transistor and the gate electrode of the reading transistor respectively, and applies the voltage having the second polarity opposite to the first polarity with respect to the drain region of the writing transistor and the drain region of the reading transistor respectively so as to eject the electric charges stored in the floating gates to both the drain region of the writing transistor and the drain region of the reading transistor, respectively.

With employment of the above-explained structure, the electric charges stored in the floating gates are ejected to the drain region of the writing transistor and the drain region of the reading transistor respectively. As a result, since the electric charges can be smoothly ejected, the electric charge ejecting time can be shortened. Also, it is possible to firmly avoid that the electric charges are left in the floating gate. Accordingly, an ejection efficiency of the electric charges can be improved.

In the imaging apparatus of the present invention, the writing transistor injects the electric charges based upon a channel hot electron injection.

With employment of the above-described structure, the injection speed of the electric charges can be improved.

In the imaging apparatus of the present invention, the writing transistor injects the electric charges based upon a tunnel electron injection.

With employment of the above-described structure, during the storing time period of the electric charges, it is possible to suppress that a dark current is produced from the drain region of the writing transistor, and also, it is possible to provide an image having a high image quality with containing a small amount of noises.

In the imaging apparatus of the present invention, the photoelectric converting portion is a photoelectric converting film provided above the semiconductor substrate.

In the imaging apparatus of the present invention, the photoelectric converting film is constructed by amorphous silicon, a CIGS (copper, indium, gallium, selenium)-series material, or an organic material.

A method for driving a solid-state imaging element, according to another aspect of the present invention, which includes a photoelectric converting portion in each of a plurality of pixel portions, and a transistor which includes an electric charge storage portion provided above a semiconductor substrate; the method includes: storing electric charges generated in each of the photoelectric converting portions into the electric charge storage portion; and ejecting the electric charges stored in the electric charge storage portion to a drain region of the transistor.

In the method for driving the solid-state imaging element according to the present invention, includes applying a voltage having a first polarity to a gate electrode of the transistor and applying another voltage having a second polarity opposite to the first polarity to the drain region of the transistor so as to eject the electric charges stored in the charge storage portion to the drain region.

In accordance with the driving method for the solid-state imaging element of the present invention, each of the plurality of the pixel portions has two sets of the transistors, wherein one transistor is a writing transistor which stores the electric charges by injecting the electric charges to the electric charge storage portion, and the other transistor is a reading transistor which reads a signal in response to the electric charges stored in the electric charge storage portion; and the electric charge storage portion corresponds to a floating gate, while the floating gate included in the writing transistor has been electrically connected to the floating gate included in the reading transistor; the method includes: applying the voltage having the first polarity with respect to the gate electrode of the writing transistor and the gate electrode of the reading transistor respectively, and applying the voltage having the second polarity opposite to the first polarity with respect to the drain region of the writing transistor and the drain region of the reading transistor respectively so as to eject the electric charges stored in the floating gates to both the drain region of the writing transistor and the drain region of the reading transistor, respectively.

In the method for driving the solid-state imaging element according to the present invention, the writing transistor is driven in such a manner that the electric charges are injected based upon a channel hot electron injection.

In the method for driving the solid-state imaging element according to the present invention, the writing transistor is driven in such a manner that the electric charges are injected based upon a tunnel electron injection.

In the method for driving the solid-state imaging element according to the present invention, the photoelectric converting portion is a photoelectric converting film provided above the semiconductor substrate.

In the method for driving the solid-state imaging element according to the present invention, the photoelectric converting film is constructed by amorphous silicon, a CIGS (copper, indium, gallium, selenium)-series material, or an organic material.

In accordance with the present invention, the imaging apparatus and the method for driving the solid-state imaging element can be provided, which can erase the electric charges stored in the electric charge storage portions, while suppressing the noises.

### BRIEF DESCRIPTION OF THE DRAWINGS

FIGS. 1A and 1B are a schematic diagram for schematically showing a structure of a solid-state imaging element in order to describe an embodiment mode of the present invention;

FIG. 2 is a sectional view for schematically representing a structure of a pixel portion indicated in FIG. 1A;

FIG. 3 is an equivalent circuit diagram of the pixel portion shown in FIG. 1A.

FIG. 4 is a timing chart for describing a first example as to imaging operations of an imaging apparatus on which the solid-state imaging element indicated in FIG. 1A is mounted;

FIG. 5 is a timing chart for describing a second example as to imaging operations of an imaging apparatus on which the solid-state imaging element indicated in FIG. 1A is mounted; and

FIG. 6 is a sectional view for schematically indicating another structural example as to the pixel portion of the solid-state imaging element represented in FIG. 1A.

### DESCRIPTION OF EXEMPLARY EMBODIMENTS

A description is made of a solid-state imaging element in order to explain one embodiment mode of the present invention with reference to drawings. The above-described solid-state imaging element is mounted on an imaging apparatus such as a digital camera and a digital video camera.

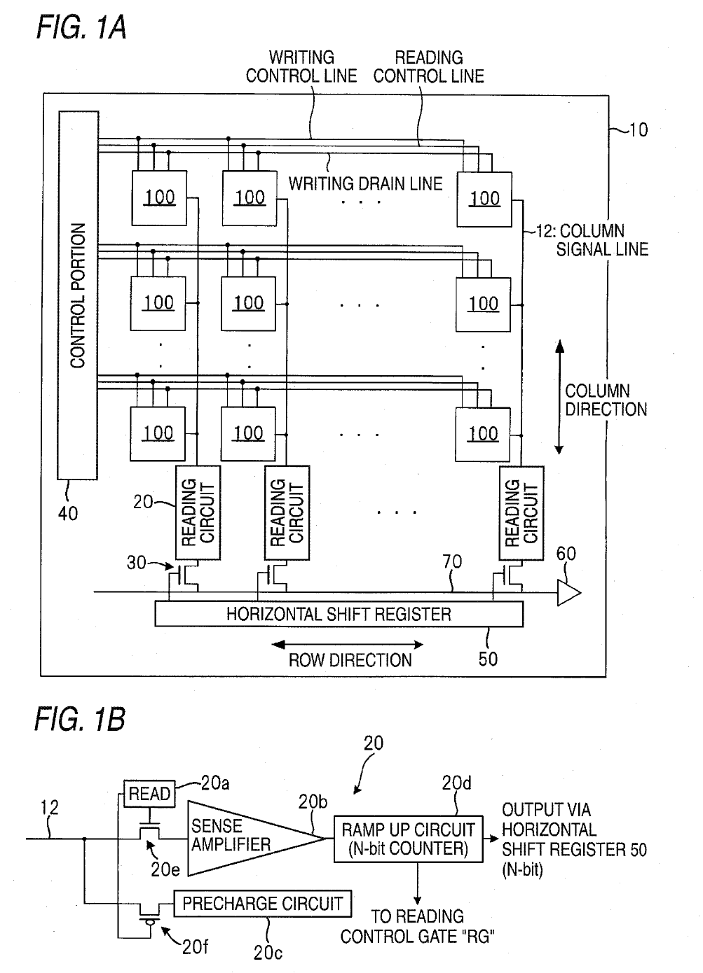

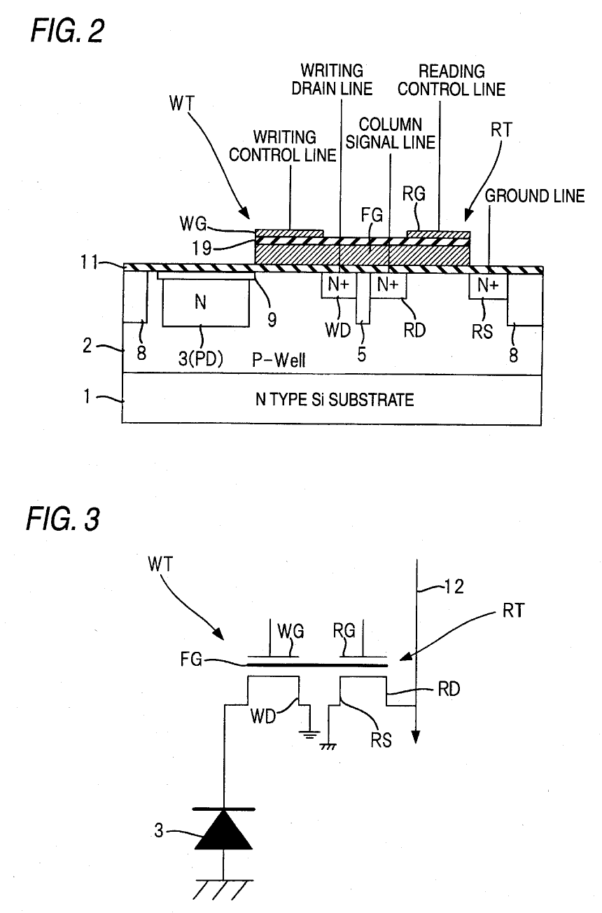

FIG. 1A is a plane view for schematically showing a structure of a solid-state imaging element 10 in order to describe the embodiment mode of the present invention. FIG. 2 is a sectional view for schematically indicating a structure of a pixel portion 100 represented in FIG. 1A. FIG. 3 is an equivalent circuit diagram of the pixel portion 100 indicated in FIG. 2.

The solid-state imaging element 10 is equipped with a plurality of pixel portions 100 which have been arranged in an array shape (in this embodiment mode, regular lattice shape) along a row direction and a column direction on the same plane, while the row direction and the column direction are intersected with each other at a right angle.

Each of the pixel portions 100 is provided with an N type silicon substrate 1 and an N type impurity layer 3 formed in such a semiconductor substrate constructed of a P well layer 2 formed on the above-described N type silicon substrate 1. The N type impurity layer 3 is formed in the P well layer 2, and since this N type impurity layer 3 and the P well layer 2 are connected to each other in a PN junction form, a photodiode (PD) is formed which functions as a photoelectric converting portion. In the below-mentioned description, the N type impurity layer 3 will be referred to as a “photoelectric converting portion 3.” The photoelectric converting portion 3 has been constructed in the form of a so-called “embedded type photodiode” in which a P type impurity layer 9 has been formed on a surface of this photoelectric converting portion 3 in order to achieve a complete depletion, and also to suppress a dark current.

A reading portion is formed on the semiconductor substrate 1, while the reading portion can read voltage signals (will also be referred as “imaging signals” hereinafter) outside the solid-state imaging element 10 in response to electric charges generated in the photoelectric converting portion 3.

The above-described reading portion is provided with a writing transistor “WT” and a reading transistor “RT.” Both the writing transistor “WT” and the reading transistor “RT” are isolated from each other by an element isolation region 5 which is formed to be slightly separated from the photoelectric converting portion 3 on the right neighbor side. Also, structural elements of the respective pixel portions 100 within the P well layer 3 are isolated from each other by the element isolation region 8.

As element isolation methods, a LOCOS (Local Oxidation of Silicon) method, an STI (Shallow Trench Isolation) method, a high-concentration impurity ion injection method, and other methods may be applied.

The writing transistor “WT” is manufactured in the form of such a MOS transistor: That is, the MOS transistor is provided with: the photoelectric converting portion 3 functioning as a source region thereof; a writing drain “WD” corresponding to a drain region thereof constructed of an N type impurity having high concentration which is separated from the photoelectric converting portion 3 on the right side; a writing control gate “WG” corresponding to a gate electrode thereof provided between the photoelectric converting portion 3 and the writing drain “WD” via an oxide film 11 above the semiconductor substrate 1; and a floating gate “FG” thereof provided between the control gate “WG” and the oxide film 11.

As an electric conducting material which constructs the above-described writing control gate “WG”, for instance, polysilicon may be employed. Alternatively, such a doped polysilicon that phosphorus (P), arsenic (As), and boron (B) have been doped in high concentration may be employed. Otherwise, Silicide and Self-align Silicide may be alternatively employed, in which various sorts of metals such as titanium (Ti) and tungsten (W) have been combined with silicon.

The reading transistor “RT” is manufactured in the form of such a MOS transistor: That is, the MOS transistor is provided with: a reading drain “RD” corresponding to a drain region thereof constructed of an N type impurity having high concentration, which is provided on the right neighbor side of the element isolation region 5; a reading source “RS” corresponding to a source region thereof constructed of an N type impurity which is provided to be slightly separated from the reading drain “RD” at the right neighbor side, a reading control gate “RG” corresponding to a gate electrode provided between the reading drain “RD” and the reading source “RS” via the oxide film 11 above the semiconductor substrate 1; and a floating gate “FG” thereof provided between the reading control gate “RG” and the oxide film 11.

As to an electric conducting material which constructs the reading control gate “RG”, the same electric conducting material as that of the writing control gate “WG” may be employed. A column signal line 12 is connected to the reading drain “RD.” A ground line is connected to the reading source “RS.” Impurity concentration of the reading drain “RD” has been adjusted in order that the reading drain “RD” may be ohmic-contacted to the column signal line 12. Impurity concentration of the reading source “RS” has been adjusted in order that the reading source “RS” may be ohmic-contacted to the ground line.

The floating gate “FG” corresponds to an electrically floating electrode provided between the P type impurity layer 9 and the reading source “RS” via the oxide film 11 above the semiconductor substrate 1. Both the writing control gate “WG” and the reading control gate “RG” are provided on the floating gate “FG” via an insulating film 19 such as a silicon oxide. As to an electric conducting material which constructs the floating gate “FG”, the same electric conducting material as that of the writing control gate “WG” may be employed.

It should be understood that the floating gate “FG” may be formed not only in a single sheet structure which is commonly used with respect to the writing transistor “WT” and the reading transistor “RT”, but also in two separated floating gate structures. That is, while two separated floating gates “FG” are provided with respect to the writing transistor “WT” and the reading transistor “RT”, these two-separated floating gates “FG” are electrically connected to each other by a wiring line. Alternatively, in order that electric charge injections from the photoelectric converting portion 3 to the floating gate “FG” may readily occur, the writing control gate “WG” and the photoelectric converting portion 3 may be partially overlapped with each other.

The pixel portion 100 has been formed in such a structure that light is not entered to a region except for a partial region of the photoelectric converting portion 3 by a light shielding film (not shown).

The solid-state imaging element 10 is provided with a control portion 40, a reading circuit 20, a horizontal shift register 50, and an output amplifier 60. The control portion 40 controls both the writing transistor “WT” and the reading transistor “RT.” The reading circuit 20 detects a threshold voltage of the reading transistor “RT.” The horizontal shift register 50 performs a control operation in such a manner that the threshold voltages for 1 line detected by the reading circuit 20 are sequentially read as imaging signals to a signal line 70. The output amplifier 60 is connected to the signal line 70.

The reading circuit 20 is provided in correspondence with each of columns which are constructed by a plurality of pixel portions 100 arranged along a column direction, and is connected via the column signal line 12 to the reading drain “RD” of each of the pixel portions 100 of the corresponding column. Also, the reading circuit 20 is also connected to the control portion 40.

As indicated in FIG. 1B, the reading circuit 20 is arranged by employing a reading control unit 20a, a sense amplifier 20b, a precharge circuit 20c, a ramp up circuit 20d, and transistors 20e and 20f.

When the reading control unit 20a reads a signal from the pixel portion 100, the reading control circuit 20a turns ON the transistor 20f so as to apply a drain voltage from the precharge circuit 20c via the column signal line 12 to the reading drain “RD” of the pixel portion 100 (namely, precharge). Next, the reading control unit 20a turns ON the transistor 20e so as to conduct the reading drain “RD” of the pixel portion 100 and the sense amplifier 20b.

The sense amplifier 20b monitors a voltage appeared at the reading drain “RD” of the pixel portion 100, and detects that this monitored voltage has changed, and then, notifies the detection result to the ramp up circuit 20d. For example, the sense amplifier 20b detects that the drain voltage precharged by the precharge circuit 20c has been dropped, and thus, inverts the output signal of the sense amplifier 20b.

While the ramp up circuit 20d has contained an N-bit counter, the ramp up circuit 20d applies such a ramp waveform voltage which is gradually increased, or gradually decreased, to the reading control gate “RG” of the pixel portion 100 via the control portion 40, and outputs a counter value (namely, “N” pieces of “1” and “0” are combined with each other) which corresponds to the values of the ramp waveform voltage.

When a voltage of the reading control gate “RG” exceeds the threshold voltage of the reading transistor “RT”, the reading transistor “RT” becomes conductive. At this time, the potential of the precharged column signal line 12 is decreased. This potential drop is detected by the sense amplifier 20b, so that an inverted signal is outputted from the sense amplifier 20b. The ramp up circuit 20d holds (latches) a count value which corresponds to a voltage of a ramp waveform voltage at a time instant when this inverted voltage is received by the ramp up circuit 20d. As a result, a change (imaging signal) of threshold voltages can be read out as a digital value (combination between 1 and 0).

When one horizontal selecting transistor 30 is selected by the horizontal shift register 40, such a count value held by the ramp up circuit 20d connected to the selected horizontal selecting transistor 30 is outputted to the signal line 70, and this outputted count value is outputted as an imaging signal from the output amplifier 60.

It should also be noted that as a method for reading out a change in the threshold voltages of the reading transistor “RT” by the reading circuit 20, the present invention is not limited only to the above-described reading method. For instance, the reading circuit 20 may alternatively read such a drain current of the reading transistor “RT” as an imaging signal in the case that a constant voltage is applied to both the reading control gate “RG” and the reading drain “RD.”

The control portion 40 is connected via a writing control line, a reading control line, and a writing drain line to the writing control gate “WG”, the reading control gate “RG” and the writing drain “WD” of each of the pixel portions 100 arranged along the row direction, respectively. Impurity concentration of the writing drain “WD” has been adjusted in order that the writing drain “WD” may be ohmic-contacted to the writing drain line.

The control portion 40 controls the writing transistor “WT” so as to perform such a driving operation that electric charges generated in the photoelectric converting portion 3 are injected to the floating gate “FG” in order to store the injected electric charges into this floating gate “FG.” As methods for injecting electric charges to a floating gate “FG”, there are two electron injection methods: Namely, a CHE injection method for injecting the electric charges to the floating gate “FG” by employing channel hot electrons (CHE); and a tunnel electron injection method for injecting the electric charges to the floating gate “FG” by employing a Fowler-Nordheim (F-N) tunnel current.

Also, the control portion 40 controls the reading transistor “RT” based upon the above-explained method so as to perform such a driving operation that an imaging signal responding to the electric charges stored in the floating gate “FG” is read out.

Also, the control portion 40 performs another driving operation that the electric charges stored in the floating gate “FG” are ejected outside the pixel portion 100 so as to erase the ejected electric charges. Concretely speaking, the control portion 40 applies a voltage having a first polarity (for instance, positive polarity) to the writing drain “WD” and the reading drain “RD” respectively, and also, applies another voltage having another polarity (for example, negative polarity) opposite to the first polarity with respect to the writing control gate “WG” and the reading control gate “RG” respectively so as to eject the electric charges stored in the floating gate “FG” to both the writing drain “WD” and the reading drain “RD”, so that the control portion 40 erases the electron charges stored in the floating gate “FG.”

It should also be noted that the application of the voltage to the reading drain “RD” is performed by that the control portion 40 controls the reading control unit 20a and the precharge circuit 20a. The precharge circuit 20c can produce voltages having two different sorts of levels and can supply the produced voltages to the column signal line 12, namely, a voltage (Vᵣ) which is applied to the reading drain “RD” in order to read an imaging signal, and another voltage “V_{cc}” which is applied to the reading drain “RD” in order to erase electric charges. When the electric charges are erased, the precharge circuit 20c applies the above-described voltage (V_{cc}) to the reading drain “RD” in response to an instruction issued from the control portion 40. When the electric charges are erased, the reading control unit 20a turns OFF the transistor 20e and turns ON the transistor 20f in response to an instruction issued from the control portion 40.

It should also be understood that although the control portion 40 has been built in the solid-state imaging element 10 in FIG. 1A, the function of the control portion 40 may be alternatively provided on the side of the imaging apparatus where the solid-state imaging element 10 is mounted.

Next, a description is made of an example as to imaging operations of the solid-state imaging element 10 having the above-described structure. In the following description, a first operation example where electric charges are injected based upon the CHE injection method, and a second operation example where electric charges are injected based upon the tunnel electron injection method.

### First Operation Example

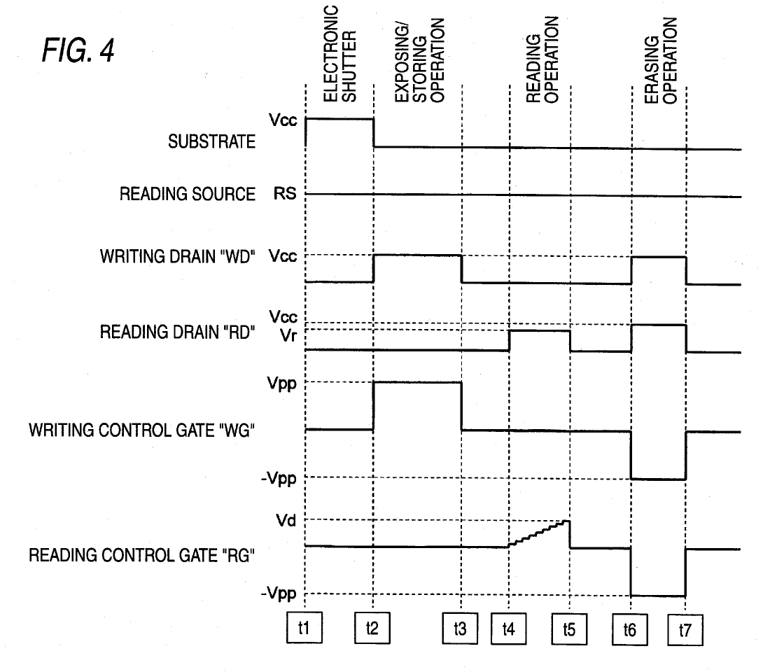

FIG. 4 is a timing chart for describing a first example as to an imaging operation of an imaging apparatus on which the solid-state imaging element 10 shown in FIG. 1A is mounted. FIG. 4 represents potential changes of respective structural portions provided in pixel portions 100 of an “i”th line in combination with a time.

Firstly, at a time instant “t1” before exposing/storing operations are commenced, as an electronic shutter operation, the control portion 40 sets a potential at the semiconductor substrate 1 to “V_{cc}” so as to eject all electric charges to the semiconductor substrate 1, which have been stored in the photoelectric converting portion 3 before the time instant “t1.” Since the above-described ejecting operation is carried out, the photoelectric converting portion 3 is brought into such a condition that no electric charge is present. Since the electric charges stored in the floating gate “FG” had been erased before the time instant “t1”, the floating gate “FG” is also reset by an erasing operation at this time instant “t1.” As a consequence, since the ejecting operation is carried out by the control portion 40 at the time instant “t1”, both the photoelectric converting portion 3 and the floating gate “FG” are brought into such conditions that electric charges are not stored.

When the elapsed time reaches a time instant “t2” corresponding to starting timing of an exposing/storing time period, the control portion 40 sets the potential at the semiconductor substrate 1 to a “Low” level. Also, the control portion 40 sets potentials at the writing control gates “WG” of all of the pixel portions 100 to “Vₚₚ(>V_{cc})”, and also, sets potentials at the writing drains “WD” thereof to “V_{cc}.” Since such a voltage setting operation is carried out, electric charges generated in the photoelectric converting portions 3 during the exposing/storing time period pass through the oxide films 11 and then are injected to the floating gates “FG” (namely, CHE injection). In order that the control portion 40 suppresses that the electric charges are leaked from the reading drains “RD” during the exposing/storing time period, the control portion 40 sets the voltages at the reading drains “RD” of all of the pixel portions 100 to the “Low” levels. As a result, the control portion 40 can avoid that the sensitivity of the solid-state imaging element 10 is lowered.

As previously described, during the exposing/storing time period defined from the time instant “t2” to a time instant “t3”, storing operations of the electric charges are carried out in all of the pixel portions 100 at the same time. It should also be noted that the film thicknesses of the oxide films 11 and the like have been adjusted in order that the electric charges generated in the photoelectric converting portions 3 can be quickly and firmly injected to the floating gates “FG.”

When the elapsed time reaches the time instant “t3” corresponding to end timing of the exposing/storing time period, the control portion 40 sets the potentials at the writing control gates “WG” and the potentials at the writing drains “WD” of all of the pixel portions 100 to “Low” levels, respectively. As a result, such electric charges which are generated in the photoelectric converting portions 3 of all of the pixel portions 100 after the above-explained time instant “t3” are not injected to the floating gates “FG”, so that the storing operations of the electric charges are accomplished.

When the elapsed time reaches a time instant “t4” corresponding to starting timing of a reading time period for an imaging signal, the control portion 40 sets potentials at the reading drains “RD” of the respective pixel portions 100 of the “i”th line to “Vᵣ(<V_{cc})”, and starts to apply ramp waveform voltages to the reading control gates “RG” of the respective pixel portions 100 of the “i”th line. Then, a count value corresponding to a value of such a ramp waveform voltage at a time instant when the potential of the reading drain “RD” of the “i”th line is decreased is held within each of the reading circuit 20, and this count value is outputted as an imaging signal from the output amplifier 60.

The control portion 40 performs signal reading operations for the time instant “t4” to the time instant “t5” by shifting the timing every line. Since the reading operation of the signal is carried out every line, read waiting time periods defined from the time instant “t3” to the time instant “t4” are different from each other every line; and in the longest line, the read waiting time period may considerably exceed 1 msec. Accordingly, the structures of the oxide films 11 have been adjusted in order that leakage of the electric charges does not occur during both the exposing/storing time period and the read waiting time periods.

After the imaging signals are sequentially read out from all of the pixel portions 100, the control portion 40 sets potentials at the writing control gates “WG” and the potentials at the reading control gates “RG” of all of the pixel portions 100 to “−Vₚₚ”, and also, sets the potentials at the writing drains “WD” and the reading drains “RD” of all of the pixel portions 100 to “V_{cc}” (time instant “t6”). It should also be noted that at this time, the potential of the semiconductor substrate 1 is not changed. As a result, all of the electric charges which have been so far stored in the floating gates “FG” are ejected to both the writing drains “WD” and the read drains “RD.” The writing drains “WD” and the reading drains “RD” are high-concentration impurity layers respectively, and the potentials thereof are deep, so that all of the electric charges can be firmly ejected to these writing and reading drains “WD” and “RD.”

It should also be understood that every time the reading operations of the imaging signals from the respective pixel portions 100 in an arbitrary line are accomplished, the electric charges stored in the floating gates “FG” of the respective pixel portions 100 in this arbitrary line may be alternatively erased. In other words, erasing of electric charges for each of the lines may be independently carried out.

### Second Operation Example

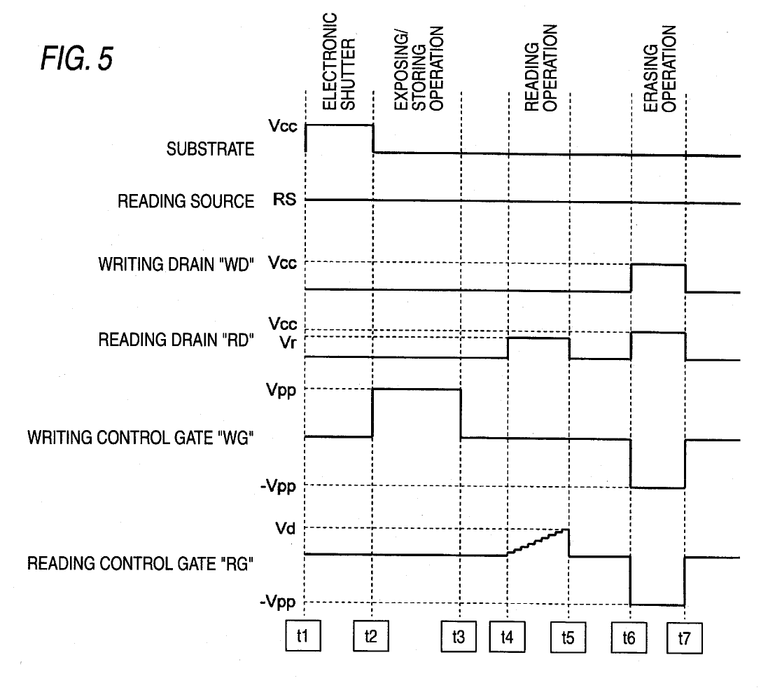

FIG. 5 is a timing chart for describing a second example as to an imaging operation of an imaging apparatus on which the solid-state imaging element 10 shown in FIG. 1A is mounted. FIG. 5 represents potential changes of respective structural portions provided in pixel portions 100 of an “i”th line in combination with a time. FIG. 5 has the following different point from that of FIG. 4: That is, potentials at the waiting drains “WD” have been set to “Low” levels during the exposing/storing time period. As a result, electric charges generated in the photoelectric converting portions 3 are injected to the floating gates “FG” based upon an F-N tunnel current.

As previously described, in accordance with the above-explained imaging apparatus, the electric charges which have been stored in the floating gates “FG” of the pixel portions 100 are ejected to the drain regions of the writing transistors “WT” and the drain regions of the reading transistors “RT” as to the above-explained pixel portions 100. As a result, as compared with the conventional solid-state imaging element in which the electric charges are ejected to the semiconductor substrate, the imaging apparatus of the second operation example can avoid that the oxide films 11 are deteriorated, the potential at the semiconductor substrate 1 is modulated, the dark currents are increased which are produced in the vicinity of the source-to-drain junction portions of both the writing transistors “WT” and the reading transistors “RT”, and also, can avoid other problems. Moreover, the above-described imaging apparatus of the second operation example can avoid that the electric charges ejected from the floating gates “FG” are left in the semiconductor substrate 1. As a result, such a risk that the remaining electric charges are mixed to an imaging signal of a next frame as noises can also be reduced.

Also, in the above-described imaging apparatus, since such a driving operation is employed that the electric charges are injected to the floating gates “FG” based upon the CHE injection, the injection speed of the electric charges can be improved. Also, in the above-described imaging apparatus, such a driving operation is employed that the electric charges are injected to the floating gates “FG” based upon the tunnel electron injection. As a result, the imaging apparatus can suppress that the dark currents are generated from the writing drains “WD” during the electric charge storing time period with respect to the floating gates “FG”, and therefore, can provide images having high image qualities, which contain a smaller amount of noises.

The above-explained description has exemplified that the electric charges stored in the floating gates “FG” are ejected to both the writing drains “WD” and the reading drains “RD.” Alternatively, the electric charges may be ejected to any one of these writing drains “WD” and reading drains “RD.” In other words, within the time periods defined between the time instant “t6” and the time instant “t7” represented in FIG. 4 and FIG. 5, such a driving operation may be alternatively employed that the potentials at either the writing drains “WD” and the reading drains “RD” are set to the “Low” levels.

Also, the above-explained embodiment mode has exemplified such a structure that one pixel portion 100 contains two sets of the writing transistor “WT” and the reading transistor “RT.” Alternatively, the respective functions as to the writing transistor “WT” and the reading transistor “RT” may be realized by a single transistor.

For instance, in FIG. 2, another structure may be alternatively constructed in which the reading transistor “RT” may be omitted, and the reading circuit 20 may be connected via the column signal line 12 to the writing drain “WD.” In the case of the above-described alternative structure, during the exposing/storing time period, the potential of the writing control gate “WG” is set to “Vₚₚ”, and the potential of the writing drain “WD” is set to either “V_{cc}” or the “Low” level, so that the electric charges can be stored in the floating gate “FG.” Also, in the signal reading time period, the potential of the writing drain “WD” is set to “Vᵣ”, and also, the ramp waveform voltage is applied to the writing control gate “WG”, so that the imaging signal may be read out. Also, in the electric charge erasing time period, the potential of the writing drain “WD” is set to “V_{cc}”, and the potential of the writing control gate “WG” is set to “−Vₚₚ”, so that the electric charges can be ejected to the writing drain “WD.”

In such a case that electric charges are stored, imaging signals are read out, and electric charges are erased by employing a single transistor, only a writing drain “WD” becomes an ejection path for the electric charges when the electric charges are erased. To the contrary, in accordance with the structure shown in FIG. 2, two sets of the writing drain “WD” and the reading drain “RD” constitute the ejection path for the electric charges when the electric charges are erased. As a result, since the electric charges can be smoothly ejected, the electric charge ejecting time can be shortened. Also, it is possible to firmly avoid that the electric charges are left in the floating gate “FG.” Accordingly, an ejection efficiency of the electric charges can be improved. As a result, such a high-quality imaging operation can be carried out, while an appearance of after images may be suppressed.

As previously explained, in such a case that the reading portion is realized by employing a single transistor, the structure other than the MOS structure may be alternatively employed in this single transistor. For instance, an MNOS type transistor structure may be employed in which the floating gate “FG” shown in FIG. 2 is made of a nitride film, and the writing control gate “WG” is directly formed on the above-described nitride film. Alternatively, such an MONOS type transistor structure may be employed in which the floating gate “FG” represented in FIG. 2 is made by a nitride film. In the case of the above-explained MNOS type transistor structure, a trap level within such a film made of the nitride film and the oxide film 11 may function as an electric charge storing portion for storing thereinto the electric charges. In the case of the above-explained MONOS type transistor structure, the nitride film may function as an electric charge storing portion for storing thereinto the electric charges.

Although the above-explained embodiment mode has exemplified such an example that the photoelectric converting portion 3 has been formed in the semiconductor substrate 1, the present invention is not limited only to this example.

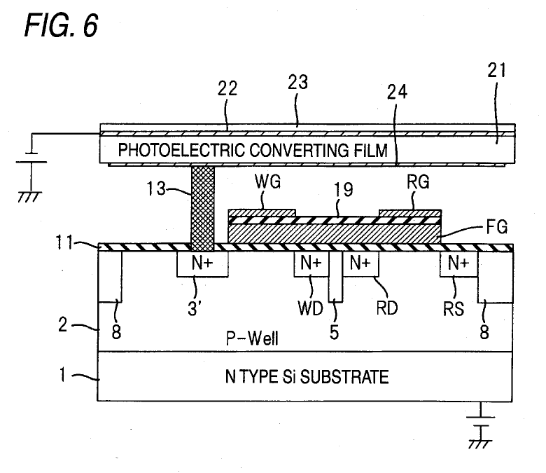

FIG. 6 is a sectional view for schematically indicating another structural example as to the pixel portion 100 of the solid-state imaging element 10 shown in FIG. 1A. The pixel portion indicated in FIG. 6 is constructed in such a manner that an N type impurity layer 3′ is provided instead of the P type impurity layer 9 and the photoelectric converting portion 3 of the pixel portion 100 shown in FIG. 2. The N type impurity layer 3′ functions as a source region of a writing transistor “WT.”

A pixel electrode 24 isolated every pixel portion 100 is formed above the semiconductor substrate 1. A photoelectric converting film 21 is formed on the pixel electrode 24, and a counter electrode 22 is formed on the photoelectric converting film 21. A protection film 23 is formed on the counter electrode 22, while the protection film 23 is transparent with respect to incident light.

The counter electrode 22 is manufactured by utilizing an electric conducting material (for instance, metal compound such as ITO, or a very thin metal film etc.) which penetrates therethrough incident light. The counter electrode 22 has been manufactured as a single sheet of an electrode which is commonly used in all of the pixel portions 100. The electric converting film 21 is such a film manufactured by containing either an organic photoelectric converting material or an inorganic photoelectric converting material, which generates electric charges in response to the incident light. The photoelectric converting film 21 has been manufactured as a single sheet of a film which is commonly used in all of the pixel portions 100. As the photoelectric converting film 21, for example, amorphous silicon, a CIGS (copper, indium, gallium, selenium)-series material, and the like may be utilized.

It should also be noted that both the counter electrode 22 and the photoelectric converting film 21 may be alternatively separated from each other every pixel portion 100. As to the counter electrode 22, for instance, such a structure may be realized in which electrodes having rectangular shapes are commonly connected to each other.

The N type impurity layer 3′ is connected to the pixel electrode 24 via a plug 13 made of an electric conducting material such as aluminium, so that the N type impurity layer 3′ is electrically connected to the photoelectric converting film 21.

In the solid-state imaging element having the above-described structure, a potential at the semiconductor substrate 1 is set to “V_{cc}” so as to eject electric charges within the N type impurity layer 3′ to the semiconductor substrate 1. Thereafter, an exposing/storing time period is commenced. When the exposing/storing time period is commenced, a potential at the writing drain “WD” is set to either the “V_{cc}” level or a “Low” level, and a potential at the writing control gate “WG” is set to “Vₚₚ.” As a result, electric charges which have been generated in the photoelectric converting film 21 during the exposing/storing time period pass through the pixel electrode 24 and the plug 13, and then, are moved to the N type impurity layer 3′. Thereafter, the electric charges which have been moved to the N type impurity layer 3′ pass through the oxide film 11, and then, are injected to the floating gate “FG.” It should be understood that operations of the solid-state imaging element shown in FIG. 6 after the above-described exposing/storing time period are identical to those described with reference to FIG. 4 and FIG. 5.

As previously explained, even in the solid-state imaging element having such a structure that the photoelectric converting portion has been stacked over the semiconductor substrate 1, the above-described effect can be achieved. In accordance with the structure shown in FIG. 6, the photoelectric converting portion has been formed above the reading portion, so that a fill factor can be made wider, and the sensitivity thereof can be improved. As a consequence, in particular, it is possible to provide images having high image qualities in low illuminance.

It should also be understood that the above-explained embodiment modes have exemplified such a case that the electric charges to be handled (namely, electric charges which are derived as imaging signals) are assumed as electrons. The same technical idea may be applied to such a case that the electric charges to be handled are assumed as holes. When the electric charges to be handled are assumed as the holes, N type regions may be merely substituted by P type regions, and polarities of voltages which are applied to the respective structural portions may be merely reversed with respect to the voltage polarities of the electron case.

What is claimed is:

1. An imaging apparatus comprising:
a photoelectric converting portion in each of a plurality of pixel portions;
a transistor which includes an electric charge storage portion provided above a semiconductor substrate so as to store thereinto electric charges generated in each of the photoelectric converting portions; and
an electric charge ejecting unit which ejects the electric charges stored in the electric charge storage portion to a drain region of the transistor.

2. The imaging apparatus according to claim 1, wherein the electric charge ejecting unit applies a voltage having a first polarity to a gate electrode of the transistor and applies another voltage having a second polarity opposite to the first polarity to the drain region of the transistor so as to eject the electric charges stored in the charge storage portion to the drain region.

3. The imaging apparatus according to claim 2, wherein each of the plurality of the pixel portions has two sets of the transistors; wherein
one transistor is a writing transistor which stores the electric charges by injecting the electric charges to the electric charge storage portion, and
the other transistor is a reading transistor which reads a signal in response to the electric charges stored in the electric charge storage portion;
the electric charge storage portion corresponds to a floating gate, while the floating gate included in the writing transistor has been electrically connected to the floating gate included in the reading transistor; and
the electric charge ejecting unit applies the voltage having the first polarity with respect to the gate electrode of the writing transistor and the gate electrode of the reading transistor respectively, and applies the voltage having the second polarity opposite to the first polarity with respect to the drain region of the writing transistor and the drain region of the reading transistor respectively so as to eject the electric charges stored in the floating gates to both the drain region of the writing transistor and the drain region of the reading transistor, respectively.

4. The imaging apparatus according to claim 3, wherein the writing transistor injects the electric charges based upon a channel hot electron injection.

5. The imaging apparatus according to claim 3, wherein the writing transistor injects the electric charges based upon a tunnel electron injection.

6. The imaging apparatus according to claim 1, wherein the photoelectric converting portion is a photoelectric converting film provided above the semiconductor substrate.

7. The imaging apparatus according to claim 6, wherein the photoelectric converting film is formed by amorphous silicon, a CIGS (copper, indium, gallium, selenium)-series material, or an organic material.

8. A driving method of a solid-state imaging element which includes a photoelectric converting portion in each of a plurality of pixel portions, and a transistor which includes an electric charge storage portion provided above a semiconductor substrate; the method comprising:
storing electric charges generated in each of the photoelectric converting portions into the electric charge storage portion; and
ejecting the electric charges stored in the electric charge storage portion to a drain region of the transistor.

9. The driving method of the solid-state imaging element according to claim 8, comprising:
applying a voltage having a first polarity to a gate electrode of the transistor and applying another voltage having a second polarity opposite to the first polarity to the drain region of the transistor so as to eject the electric charges stored in the charge storage portion to the drain region.

10. The driving method of a solid-state imaging element according to claim 9, which each of the plurality of the pixel portions has two sets of the transistors, wherein one transistor is a writing transistor which stores the electric charges by injecting the electric charges to the electric charge storage portion, and the other transistor is a reading transistor which reads a signal in response to the electric charges stored in the electric charge storage portion; and the electric charge storage portion corresponds to a floating gate, while the floating gate included in the writing transistor has been electrically connected to the floating gate included in the reading transistor; the method comprising:
applying the voltage having the first polarity with respect to the gate electrode of the writing transistor and the gate electrode of the reading transistor respectively, and applying the voltage having the second polarity opposite to the first polarity with respect to the drain region of the writing transistor and the drain region of the reading transistor respectively so as to eject the electric charges stored in the floating gates to both the drain region of the writing transistor and the drain region of the reading transistor, respectively.

11. The driving method of a solid-state imaging element according to claim 10, wherein the writing transistor is driven in such a manner that the electric charges are injected based upon a channel hot electron injection.

12. The driving method of a solid-state imaging element according to claim 10, wherein the writing transistor is driven in such a manner that the electric charges are injected based upon a tunnel electron injection.

13. The driving method of a solid-state imaging element according to claim 8, wherein the photoelectric converting portion is a photoelectric converting film provided above the semiconductor substrate.

14. The driving method of a solid-state imaging element according to claim 13, wherein the photoelectric converting film is constructed by amorphous silicon, a CIGS (copper, indium, gallium, selenium)-series material, or an organic material.
